(19) United States
(12) Patent Application Publication
(10) Pub. No.: US 2026/0190623 A1
(43) Pub. Date: Jul. 2, 2026

(54) Display Device

(71) Applicant: LG Display Co., Ltd., Seoul (KR)

(72) Inventor: Dongmin Lim, Seoul (KR)

(21) Appl. No.: 19/257,914

(22) Filed: Jul. 2, 2025

(30) Foreign Application Priority Data
Dec. 26, 2024 (KR) 10-2024-0197747

(51) Int. Cl. H10K 59/121; H10K 59/123; H10K 59/126; H10K 59/131

(52) U.S. Cl. CPC H10K 59/1213; H10K 59/123; H10K 59/126; H10K 59/131

(57) ABSTRACT

A display device includes pixels, wherein each pixel includes a light emission area including a light-emitting element and a circuit area including a driving transistor, wherein the circuit area includes: a first contact structure via which a first semiconductor layer is electrically connected to a light shielding layer; a second contact structure via which a first electrode is electrically connected to a gate electrode of the driving transistor and to a second semiconductor layer; and a third contact structure via which an anode electrode layer extending from an anode electrode of the light-emitting element is electrically connected to a semiconductor layer of the driving transistor and to the light shielding layer. Thus, a low-reflective metal is applied as a material of a gate electrode, such that reflectance of a display panel is lowered.

### CROSS REFERENCE TO RELATED APPLICATION

The present application claims priority to Republic of Korea Patent Application No. 10-2024-0197747, filed December 26, 2024, which is hereby incorporated by reference in its entirety.

### BACKGROUND

### Field

The present disclosure relates to a display device capable of coping with high-speed operation of a display panel.

### Description of Related Art

An organic light-emitting display device is a self-emission display device. Unlike the liquid crystal display device, a separate light source is not required in the organic light-emitting display device. Thus, the organic light-emitting display device may be manufactured in a lightweight and thin manner. In addition, the organic light-emitting display device is advantageous in terms of power consumption due to low voltage operation, and has excellent color gamut, fast response speed, large viewing angle, and high contrast ratio (CR), and thus is being studied as a next-generation display.

Display devices are continuously being improved to increase the resolution and luminance of the screen to provide clear images to users.

### SUMMARY

As a technology for reducing the reflectance of the display panel, there is a technology for depositing a low-reflective metal under a line. The low reflective metal may be applied as a material of the light shielding layer. However, due to the occurrence of the residual film during a single etching of the low reflective metal, it is difficult to apply the low-reflective metal as the material of the gate electrode. For example, a gate insulating layer exposure process is performed to form a contact structure of a pixel. However, there is a possibility that a problem in terms of the operation may occur due to the low-reflective metal residual film.

Accordingly, the inventors of the present disclosure have invented a display device in which a gate insulating layer exposure process as a defect generation process is removed by changing a contact structure of a pixel in a situation in which it is difficult to apply the low reflective metal as the material of the gate electrode due to a process problem, so that the low reflective metal may be applied as the material of the gate electrode, thereby reducing the reflectance of the display panel.

A purpose of the present disclosure is to provide a display device capable of reducing reflectance of a display panel.

Purposes according to the present disclosure are not limited to the above-mentioned purpose. Other purposes and advantages according to the present disclosure that are not mentioned may be understood based on following descriptions and may be more clearly understood based on embodiments according to the present disclosure. Further, it will be easily understood that the purposes and advantages according to the present disclosure may be realized using means shown in the claims or combinations thereof.

A display device according to an embodiment of the present disclosure includes pixels, wherein each pixel includes a light emission area including a light-emitting element and a circuit area including a driving transistor, wherein the circuit area includes: a first contact structure via which a first semiconductor layer is electrically connected to a light shielding layer disposed in the circuit area; a second contact structure via which a first electrode is electrically connected to a gate electrode of the driving transistor and to a second semiconductor layer spaced from the first semiconductor layer such that the gate electrode of the driving transistor is electrically connected to the second semiconductor layer; and a third contact structure via which an anode electrode layer extending from an anode electrode of the light-emitting element is electrically connected to a semiconductor layer of the driving transistor and to the light shielding layer.

According to an embodiment of the present disclosure, the display device includes the first contact structure disposed on the line connected to the pixel. Via the first contact structure, the semiconductor layer instead of the gate electrode layer is in contact with the light shielding layer, thereby eliminating a gate electrode layer etching process for forming the contact hole. Thus, the low-reflective metal may be applied as a material of the gate electrode, and the reflectance of the display panel may be lowered.

In addition, the display device includes the second contact structure in the circuit area. The second contact structure includes the anode electrode layer and the second contact hole. The anode electrode layer of the pixel is in contact with the gate electrode and the semiconductor layer via the second contact hole extending through the planarization layer 128 and the protective layer instead of the contact hole extending through the gate insulating layer. This is because in one side around the position at which the second contact hole contacts the semiconductor layer, the gate electrode and the gate insulating layer are omitted, such that the protective layer is disposed on the semiconductor layer. Thus, in forming the second contact structure, the etching process of the gate insulating layer is omitted. Thus, the gate electrode of the driving transistor may be made of a low reflective metal. Accordingly, the display device according to the embodiment of the present disclosure may reduce the reflectance of the display panel.

In addition, since the display device includes the second contact structure via which the semiconductor layer is connected to the gate electrode of the driving transistor via the anode electrode layer made of the same material of each of the first electrode of the light-emitting element. Thus, in forming the contact hole, the etching process of the gate insulating layer coated with the low-reflective metal material may be eliminated. Accordingly, a problem caused by a metal residual film generated during an etching process of the gate insulating layer is prevented.

Further, the display device includes the third contact structure via which the semiconductor layer is in contact with the anode electrode of the light-emitting element and the light shielding layer. The contact hole does not extend through the gate insulating layer but extends through at least one of the buffer layer, the protective layer, and the planarization layer. This allows the gate electrode of the driving transistor to be made of the low reflective metal, such that the reflectance of the display panel may be reduced.

In addition, the etching process of the gate insulating layer is omitted in forming the contact structure, such that a low reflective metal may be applied as a material of the gate electrode, thereby lowering the reflectance of the display panel.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a block diagram illustrating an organic light-emitting display device according to an embodiment of the present disclosure.

FIG. 2 is a diagram illustrating a circuit of a sub-pixel in a display panel of FIG. 1 according to an embodiment of the present disclosure.

FIG. 3 is a diagram illustrating a planar layout of a pixel in the display panel of FIG. 1 according to an embodiment of the present disclosure.

FIG. 4 is an enlarged view of a circuit area of the pixel of FIG. 3 according to an embodiment of the present disclosure.

FIG. 5 is a cross-sectional view of a I-I' area of a first contact structure in the circuit area of the pixel of FIG. 4 according to an embodiment of the present disclosure.

FIG. 6 is a cross-sectional view of a II-II’ area of a second contact structure in the circuit area of the pixel of FIG. 4 according to an embodiment of the present disclosure.

FIG. 7 is a cross-sectional view of a III-III’ area of a third contact structure in the circuit area of the pixel of FIG. 4 according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items.

Expression such as "at least one of" when preceding a list of elements may modify an entirety of the list of elements and may not modify the individual elements of the list. In interpretation of numerical values, an error or tolerance therein may occur even when there is no explicit description thereof.

In addition, it will also be understood that when a first element or layer is referred to as being present "on" a second element or layer, the first element may be disposed directly on the second element or may be disposed indirectly on the second element with a third element or layer being disposed between the first and second elements or layers.

It will be understood that when a first element or layer is referred to as being "connected to", or "coupled to" a second element or layer, the first element may be directly connected to or coupled to the second element or layer, or one or more intervening elements or layers may be present therebetween.

In addition, it will also be understood that when an element or layer is referred to as being "between" two elements or layers, it may be the only element or layer between the two elements or layers, or one or more intervening elements or layers may also be present therebetween.

Further, as used herein, when a layer, film, area, plate, or the like is disposed "on" or "on a top" of another layer, film, area, plate, or the like, the former may directly contact the latter or still another layer, film, area, plate, or the like may be disposed between the former and the latter. As used herein, when a layer, film, area, plate, or the like is directly disposed "on" or "on a top" of another layer, film, area, plate, or the like, the former directly contacts the latter and still another layer, film, area, plate, or the like is not disposed between the former and the latter. Further, as used herein, when a layer, film, area, plate, or the like is disposed "below" or “under” another layer, film, area, plate, or the like, the former may directly contact the latter or still another layer, film, area, plate, or the like may be disposed between the former and the latter. As used herein, when a layer, film, area, plate, or the like is directly disposed "below" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms "first", "second", "third", and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Description.

In description of flow of a signal, for example, when a signal is delivered from a node A to a node B, this may include a case where the signal is transferred from the node A to the node B via another node unless a phrase 'immediately transferred' or 'directly transferred' is used. Throughout the present disclosure, "A and/or B" means A, B, or A and B, unless otherwise specified, and "C to D" means C inclusive to D inclusive unless otherwise specified.

Hereinafter, a display device that may cope with high-speed operation and may remove a front of screen (FOS) issue due to this will be described.

Hereinafter, various embodiments of the disclosure will be described in detail with reference to the accompanying drawings.

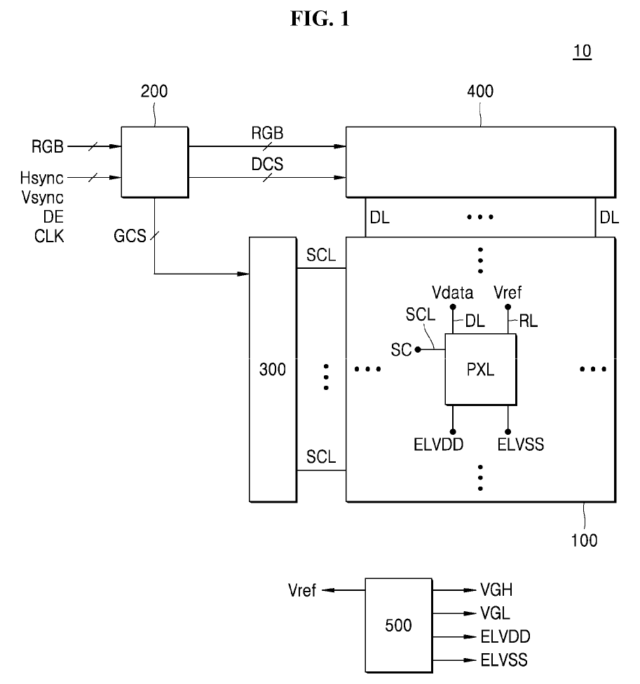

FIG. 1 is a block diagram illustrating an organic light-emitting display device according to an embodiment of the present disclosure.

Referring to FIG. 1, a display device 10 includes a display panel 100 including a plurality of pixels PXL, a controller 200, a gate driver 300 configured to supply a scan signal SC to the plurality of pixels PXL, a data driver 400 configured to supply a data voltage Vdata to the plurality of pixels PXL, and a power supply 500 configured to supply voltages necessary for driving the plurality of pixels PXL thereto.

In the display panel 100, a plurality of scan lines SCL and a plurality of data lines DL intersect each other, and each of the plurality of pixels PXL is connected to the scan line SCL and the data line DL. Specifically, one pixel PXL receives the scan signal SC via the scan line SCL, receives the data voltage Vdata via the data line DL, and receives a reference voltage Vref, a high potential driving voltage ELVDD, and a low potential driving voltage ELVSS from the power supply 500.

The scan line SCL supplies the scan signal SC and a sensing signal to the pixel PXL, and the data line DL supplies the data voltage Vdata to the pixel PXL. In addition, according to various embodiments, the scan line SCL and a sensing line for supplying the sensing signal may be individually connected to the pixel PXL.

In addition, the display panel 100 may include a power line. The plurality of pixels PXL may receive the high-potential driving voltage ELVDD and the low-potential driving voltage ELVSS via the power line. The display panel 100 may include a reference voltage line RL via which the plurality of pixels PXL may receive the reference voltage Vref.

In addition, each of the pixels PXL includes a light-emitting element and a pixel circuit for driving the light-emitting element. The pixel circuit includes a plurality of switching elements, a driving element, and a capacitor. In this regard, each of the switching element and the driving element may be embodied as a thin-film transistor. In the pixel circuit, the driving element controls an amount of current to be supplied to the light-emitting element based on the data voltage to adjust an amount of light emitted from the light-emitting element. In addition, the switching element transmits the data voltage Vdata and the reference voltage Vref to the driving element and the capacitor in response to the scan signal SC.

The display panel 100 may be embodied as a non-transmissive display panel or a transmissive display panel. The transmissive display panel may be applied to a transparent display device in which an image is displayed on a screen and a real object in the background is visible to a viewer in front of the display device. The display panel 100 may be manufactured as a flexible display panel. The flexible display panel may be embodied as an OLED panel using a plastic substrate.

The pixels PXL may include red, green, and blue pixels for color realization. The pixels PXL may further include a white pixel.

Touch sensors TS may be disposed on the display panel 100. The touch input may be sensed using separate touch sensors or may be sensed using the pixels PXL. The touch sensors may be embodied as in-cell type touch sensors embedded in the display panel 100 or may be disposed on the screen of the display panel in an on-cell type or an add-on type.

The controller 200 receives image information from a host system, processes image data RGB included in the image information to be suitable for a size and resolution of the display panel 100 and supplies the processed image data RGB to the data driver 400. The controller 200 generates a gate control signal GCS and a data control signal DCS using synchronization signals, for example, a clock signal CLK, a data enable signal DE, a horizontal synchronization signal Hsync, and a vertical synchronization signal Vsync as input from an external source. The gate control signal GCS and the data control signal DCS are supplied to the gate driver 300 and the data driver 400, respectively, to control the gate driver 300 and the data driver 400.

The voltage level of the gate control signal GCS output from the controller 200 may be converted into a gate-on voltage and a gate-off voltage via a level shifter and may be supplied to the gate driver 300. The level shifter converts the low level voltage of the gate control signal GCS into the gate low voltage VGL and converts the high level voltage of the gate control signal GCS into the gate high voltage VGH. The gate control signal GCS includes a start pulse and a shift clock.

The gate driver 300 supplies the scan signal SC to the scan line SCL according to the gate control signal GCS. The gate driver 300 may be disposed on one side or each of both opposing sides of the display panel 100 in a gate in panel (GIP) manner.

The gate driver 300 outputs a scan pulse in response to a start pulse and a shift clock from the controller 200, and sequentially shifts the scan pulse according to the shift clock.

The data driver 400 converts the image data RGB into the data voltage Vdata according to the data control signal DCS and supplies the converted data voltage Vdata to the pixel PXL via the data line DL.

Although FIG. 1 illustrates that a single data driver 400 is disposed on one side of the display panel 100, the number and arrangement position of the data driver 400 are not limited thereto. That is, the data driver 400 may include a plurality of integrated circuits (IC) which may be disposed on one side of the display panel 100 in an individual manner.

The power supply 500 generates direct current (DC) power required for driving a pixel array of the display panel 100, the gate driver 300, and the data driver 400. The power supply 500 may include a charge pump, a regulator, a buck converter, a boost converter, etc.

The power supply 500 may receive an input voltage from the host system and may generate the DC voltage such as the gate high voltage VGH, the gate low voltage VGL, the high potential driving voltage ELVDD, the low potential driving voltage ELVSS, and the reference voltage Vref. The gate low voltage VGL and the gate high voltage VGH may be supplied to the gate driver 300, and the high potential driving voltage ELVDD, the low potential driving voltage ELVSS, and the reference voltage Vref may be supplied to the pixels PXL.

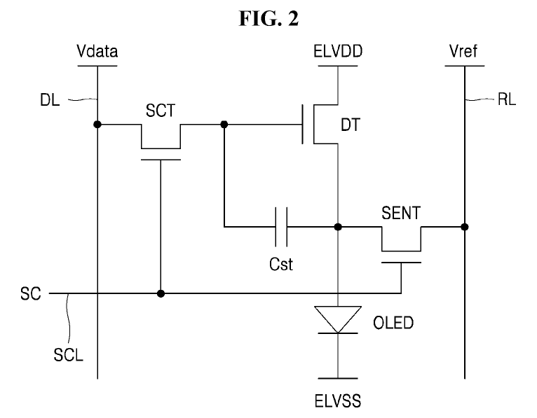

FIG. 2 is a diagram illustrating a circuit of a sub-pixel in the display panel of FIG. 1 according to an embodiment of the present disclosure.

Referring to FIG. 2, a pixel is defined by the scan line SCL, the data line DL, the power line, and the reference voltage line RL. A scan transistor SCT, a driving transistor DT, a light-emitting element OLED, a sensing transistor SENT, and a storage capacitor Cst are disposed in one pixel.

The scan transistor SCT functions to select a pixel to be driven by applying the data voltage Vdata to the driving transistor DT.

The scan transistor SCT is disposed in an area where the scan line SCL and the data line DL intersect each other. The scan transistor SCT includes a gate electrode, a source electrode, and a drain electrode. The gate electrode is connected to the scan line SCL. The source electrode is connected to the data line DL, and the drain electrode is connected to the driving transistor DT.

The driving transistor DT functions to drive the light-emitting element OLED of the pixel selected by the scan transistor SCT. The driving transistor DT includes a gate electrode, a source electrode, and a drain electrode. The gate electrode is connected to the drain electrode SD of the scan transistor SCT, the source electrode is connected to the power line to which the high potential driving voltage ELVDD is applied, and the drain electrode is connected to an anode electrode of the light-emitting element OLED.

The storage capacitor Cst serves to sample the data voltage Vdata. The storage capacitor Cst includes one electrode and the other electrode. One electrode of the storage capacitor Cst is connected to a node between the drain electrode of the scan transistor SCT and the gate electrode of the driving transistor DT, and the other electrode of the storage capacitor Cst is connected to a node between the drain electrode of the driving transistor DT and the anode electrode of the light-emitting element OLED.

The light-emitting element OLED is configured to emit light by itself, and the intensity of light emission therefrom is adjusted based on an amount of current flowing therethrough. For example, the light-emitting element OLED may be embodied as an organic light-emitting diode. The light-emitting element OLED includes the anode electrode, a light-emitting layer, and a cathode electrode.

The anode electrode of the light-emitting element OLED is connected to the drain electrode of the driving transistor DT and the other electrode of the storage capacitor Cst, the cathode electrode of the light-emitting element OLED is connected to the power line to which the low-potential driving voltage ELVSS is applied, and the light-emitting layer of the light-emitting element OLED is disposed between and connected to the anode electrode and the cathode electrode.

The sensing transistor SENT is used to initialize the anode electrode of the light-emitting element OLED and the other electrode of the storage capacitor Cst with the reference voltage Vref or to sense pixel characteristics. The sensing transistor SENT includes a gate electrode, a source electrode, and a drain electrode.

The gate electrode of the sensing transistor SENT is connected to the scan line SCL, and the drain electrode of the sensing transistor SENT is connected to the anode electrode of the light-emitting element OLED, the drain electrode of the driving transistor DT, and the other electrode of the storage capacitor Cst. The source electrode of the sensing transistor SENT is connected to the reference voltage line RL. According to various embodiments, the gate electrode of the sensing transistor SENT may be connected to the sensing line that supplies a separate sensing signal.

The driving transistor DT adjusts the amount of current flowing through the light-emitting element OLED based on the magnitude of the data voltage Vdata.

In addition, according to some embodiments, at least one of the transistors of the pixel circuit may be embodied as a P-type thin-film transistor or a N-type thin-film transistor. Each transistor and the driving transistor may be embodied as various transistors made of LTPS, an oxide, single silicon, an organic material, etc. The light-emitting element OLED may be a self-emitting diode such as an organic light-emitting element or a micro LED. The substrate on which the pixel is formed may be made of glass, plastic, flexible plastic, wafer, etc.

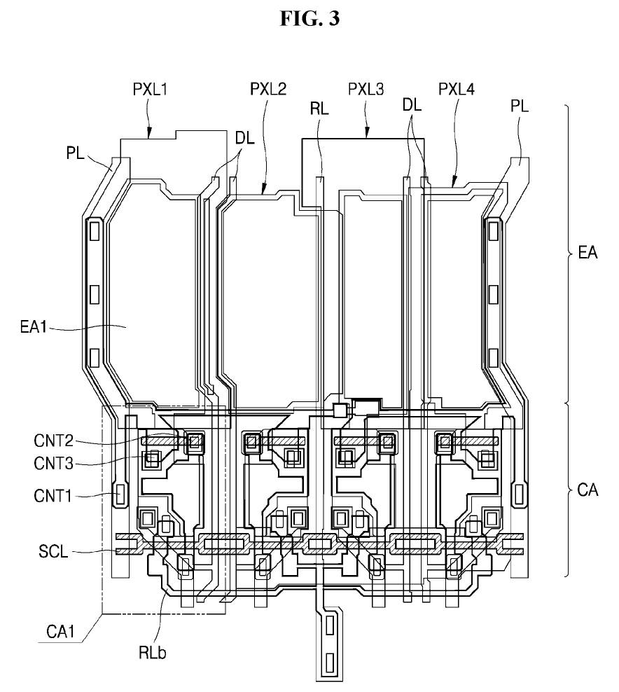

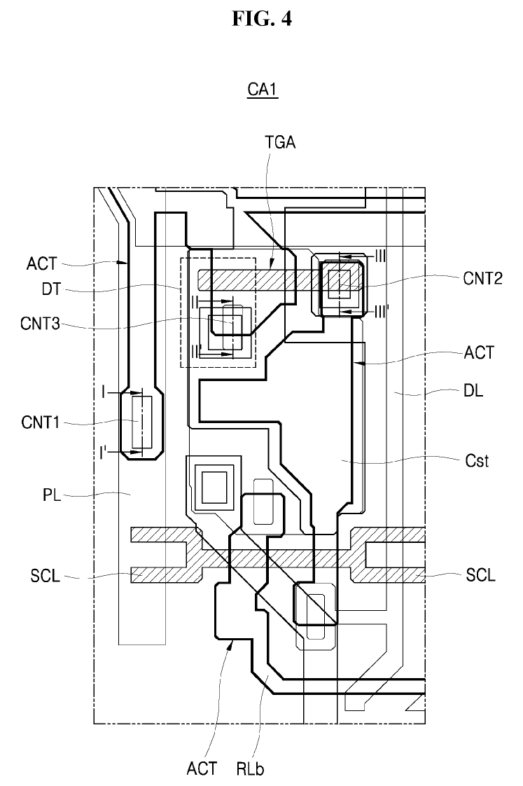

FIG. 3 is a diagram illustrating a planar layout of a pixel in the display panel of FIG. 1 according to an embodiment of the present disclosure. FIG. 4 is an enlarged view of a first circuit area CA1 of a first sib-pixel PXL1 of FIG. 3 according to an embodiment of the present disclosure.

Referring to FIG. 3 and FIG. 4, a plurality of sub-pixels PXL1, PXL2, PXL3, and PXL4 are disposed in the display panel. An area of each of the sub-pixels PXL1, PXL2, PXL3, and PXL4 is divided into a light emission area EA and a circuit area CA. An anode layer, a light-emitting layer, and a cathode layer of the light-emitting element may be disposed in the light emission area EA. The driving transistor DT, the scan transistor, the sensing transistor, and the capacitor Cst may be disposed in the circuit area CA.

The plurality of sub-pixels PXL1, PXL2, PXL3, and PXL4 may be arranged so as to be adjacent to each other in a row direction. The plurality of sub-pixels PXL1, PXL2, PXL3, and PXL4 may include R(Red), W(White), B(Blue), and G(Green) sub-pixels which may respectively include organic light-emitting elements respectively capable of emitting light of R(Red), W(White), B(Blue), and G(Green) colors. This is merely one embodiment. The plurality of sub-pixels may include organic light-emitting device capable of displaying R, G, and B colors, respectively.

Each of the sub-pixels PXL1, PXL2, PXL3, and PXL4 is connected to the data line DL, the scan line SCL, the reference voltage line RL, and the power line PL. The data line DL, the reference voltage line RL, and the power line PL may extend in a column direction, and the scan line SCL and the sub-reference voltage line RLb branched from the reference voltage line RL may extend in a row direction.

In the circuit area CA, the line connected to each of the sub-pixels PXL1, PXL2, PXL3, and PXL4 may be embodied as the semiconductor layer ACT. As shown in FIG. 4, each of the lines except for the gate electrode TGA of the driving transistor DT may be embodied as the semiconductor layer ACT. In this regard, the line may be at least one of the power line PL for supplying the high potential driving voltage, the data line DL for supplying the data voltage, the reference voltage line RL for supplying the reference voltage, and the sub-reference voltage line RLb.

In addition, a first contact structure CNT1 may be formed on each of the lines. For example, the first contact structure CNT1 may be formed on at least one of the power line PL, the data line DL, the reference voltage line RL and the sub-reference voltage line RLb. The first contact structure CNT1 may include a contact hole extending through a buffer layer 122. The semiconductor layer ACT may be disposed so as to be in contact with a light shielding layer 121 via the contact hole.

In addition, in the circuit area CA, a second contact structure CNT2 via which an anode electrode layer 131 of the light-emitting element is in contact with the semiconductor layer ACT and the gate electrode TGA of the driving transistor DT may be formed. For example, the gate electrode TGA may be made of at least one of Cu, MoTi, and WOx-Ⅱ or a combination thereof. The second contact structure CNT2 may include a contact hole extending through a protective layer 127 and a planarization layer 128. The anode electrode layer 131 may be disposed so as to be in contact with the gate electrode TGA and the semiconductor layer ACT via the contact hole.

In addition, in the circuit area CA, a third contact structure CNT3 via which the anode electrode layer 131 of the light-emitting element is in contact with the semiconductor layer ACT of the driving transistor DT, and the semiconductor layer ACT is in contact with the light shielding layer may be formed. The third contact structure CNT3 may include a contact hole extending through the protective layer 127 and the planarization layer 128 and the contact hole extending through the buffer layer 122. The anode electrode layer 131 may be disposed so as to be in contact with the semiconductor layer ACT via the contact hole extending through the protective layer 127 and the planarization layer 128, and the semiconductor layer ACT may be disposed so as to be in contact with the light shielding layer 121 via the contact hole extending through the buffer layer 122.

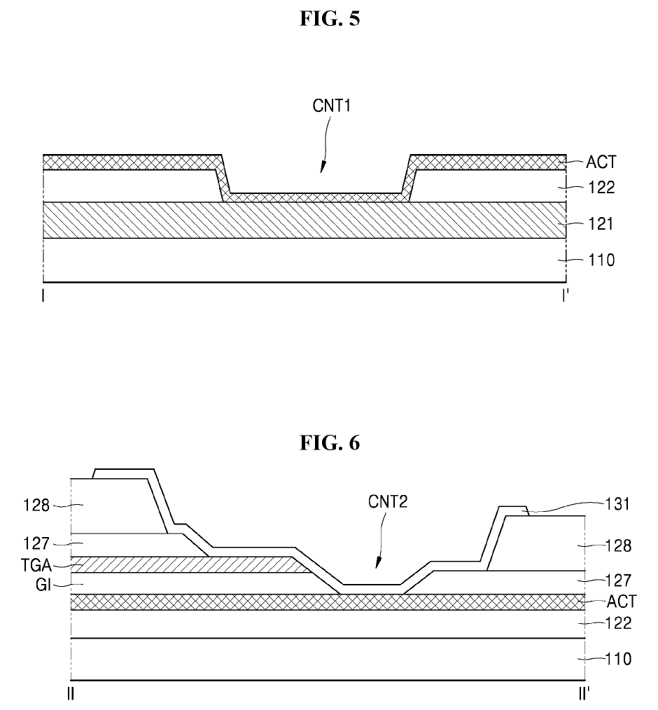

FIG. 5 is a cross-sectional view of a Ⅰ-Ⅰ' area of the first contact structure in the circuit area of the pixel of FIG. 4 according to an embodiment of the present disclosure.

Referring to FIGS. 4 and 5, the first contact structure CNT1 is formed on the power line PL in the circuit area. The first contact structure CNT1 having the structure of FIG. 5 may be formed on each of the data line DL, the reference voltage line RL, and the sub-reference voltage line RLb.

In this circuit area corresponding to the first contact structure CNT1, the light shielding layer 121 may be disposed on a substrate 110, and the buffer layer 122 may be disposed on the light shielding layer 121. The first contact structure CNT1 includes the semiconductor layer ACT and a first contact hole which extends through the buffer layer 122 so as to contact an upper surface of the light shielding layer 121. The first contact hole may be filled with, for example, the material of the semiconductor layer ACT. The semiconductor layer ACT may contact the light shielding layer 121 via the first contact hole of the first contact structure CNT1. For example, the light shielding layer 121 may be embodied as the power line PL or the data line DL. The semiconductor layer ACT that is in contact with the light shielding layer 121 via the first contact hole including the material of the semiconductor layer ACT may be embodied as a sub-power line branching from the power line PL or a sub-data line branching from the data line DL.

For example, the light shielding layer 121 may be made of at least one of Cu and WOx-Ⅱ or a combination thereof. In addition, the light shielding layer 121 may be made of a conductive material, for example, a metal material. The metal material may be one of molybdenum (Mo), aluminum (Al), chromium (Cr), gold (Au), titanium (Ti), nickel (Ni), neodymium (Nd), and copper (Cu), or an alloy thereof.

The light shielding layer 121 may act as the power line PL. In addition, the light shielding layer 121 may act as the data line DL. In addition, the light shielding layer 121 may act as the scan line SCL. Each of the power line PL, the data line DL, and the scan line SCL may be connected to the semiconductor layer ACT via the first contact structure CNT1.

Each of the power line PL, the data line DL, and the scan line SCL may be made of one of molybdenum (Mo), aluminum (Al), chromium (Cr), gold (Au), titanium (Ti), nickel (Ni), neodymium (Nd), and copper (Cu), or an alloy thereof.

The buffer layer 122 may reduce or prevent penetration of moisture, oxygen, or impurities through the substrate 110 to protect the elements of the circuit area CA. The buffer layer 122 may include multiple layers. The buffer layer 122 may include an inorganic insulating layer including silicon oxide (SiOx) or silicon nitride (SiNx). For example, the buffer layer 122 may be formed as a stack of multiple layers in which one or more inorganic insulating layers are stacked.

As described above, the display device includes the first contact structure CNT1 disposed on the line connected to the pixel. Via the first contact structure CNT1, the semiconductor layer ACT instead of the gate electrode layer is in contact with the light shielding layer 121, thereby eliminating a gate electrode layer etching process for forming the contact hole. Thus, the low-reflective metal may be applied as a material of the gate electrode, and the reflectance of the display panel may be lowered.

FIG. 6 is a cross-sectional view of a Ⅱ-Ⅱ' area of the second contact structure in the circuit area of the pixel of FIG. 4 according to an embodiment of the present disclosure.

Referring to FIGS. 4 and 6, the second contact structure CNT2 is formed in a portion of the circuit area CA in the first electrode of the pixel is connected to the gate electrode TGA of the driving transistor DT and the semiconductor layer ACT. In this regard, in the circuit area, the first electrode may be embodied as the anode electrode layer 131 made of the same material as that of the anode electrode of the light-emitting element. In the circuit area, the semiconductor layer ACT may act as one electrode of the capacitor Cst of the pixel PX. That is, in the circuit area, the anode electrode layer 131 is not electrically connected to the anode electrode of the light-emitting element and serves as a sub-line connecting the gate electrode TGA and the semiconductor layer ACT of the driving transistor DT to each other.

In the circuit aera corresponding to the second contact structure CNT2, the buffer layer 122 is disposed on the substrate 110, the semiconductor layer ACT is disposed on the buffer layer 122, a gate insulating layer GI is disposed on the semiconductor layer ACT, the gate electrode TGA is disposed on the gate insulating layer GI, the protective layer 127 is disposed on the gate electrode TGA. The planarization layer 128 is disposed on the protective layer 127. In this regard, in one side around a position at which the second contact hole contacts the semiconductor layer ACT, the gate electrode TGA and the gate insulating layer GI are omitted, such that the protective layer 127 is disposed on the semiconductor layer ACT. The second contact structure CNT2 includes a second contact hole extending through the protective layer 127 and the planarization layer 128. In one example, the second contact hole may be filled with, for example, the material of the anode electrode layer 131.

In the circuit area corresponding to the second pixel structure CNT2, the anode electrode layer 131 is in contact with the gate electrode TGA and the semiconductor layer ACT via the second contact hole of the second pixel structure CNT2 extending through the protective layer 127 and the planarization layer 128. In this regard, the semiconductor layer ACT connected to the gate electrode TGA may act as an electrode of the capacitor Cst of the pixel.

As described above, the display device includes the second contact structure CNT2 in the circuit area. The second contact structure CNT2 includes the anode electrode layer 131 and the second contact hole. The anode electrode layer 131 of the pixel PXL is in contact with the gate electrode TGA and the semiconductor layer ACT via the second contact hole extending through the planarization layer 128 and the protective layer 127 instead of the contact hole extending through the gate insulating layer GI. This is because in one side around the position at which the second contact hole contacts the semiconductor layer ACT, the gate electrode TGA and the gate insulating layer GI are omitted, such that the protective layer 127 is disposed on the semiconductor layer ACT.

Thus, in forming the second contact structure CNT2, the etching process of the gate insulating layer GI is omitted. Thus, the gate electrode of the driving transistor may be made of a low reflective metal. Accordingly, the display device according to the embodiment of the present disclosure may reduce the reflectance of the display panel.

In addition, since the display device includes the second contact structure CNT2 via which the semiconductor layer ACT is connected to the gate electrode TGA of the driving transistor DT via the anode electrode layer 131 made of the same material of each of the first electrode of the light-emitting element. Thus, in forming the contact hole, the etching process of the gate insulating layer coated with the low-reflective metal material may be eliminated. Accordingly, a problem caused by a metal residual film generated during an etching process of the gate insulating layer is prevented.

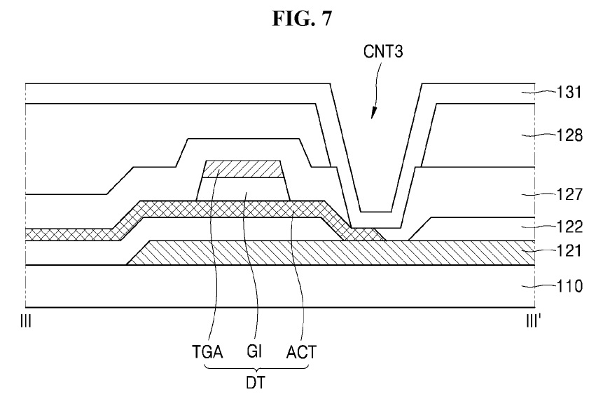

FIG. 7 is a cross-sectional view of a Ⅲ-Ⅲ' area of the third contact structure in the circuit area of the pixel of FIG. 4 according to an embodiment of the present disclosure.

Referring to FIGS. 4 and 7, the third contact structure CNT3 is formed in a portion of the circuit area CA in which the anode electrode layer 131 connected to the pixel PXL is in contact with the semiconductor layer ACT of the driving transistor DT, and the semiconductor layer ACT is in contact with the light shielding layer 121.

In the circuit area corresponding to the third contact structure CNT3, the light shielding layer 121 is disposed on the substrate 110, the buffer layer 122 is disposed on the light shielding layer 121, the semiconductor layer ACT is disposed on the buffer layer 122. A third contact hole extends through the buffer layer 122. The gate insulating layer GI is disposed on the semiconductor layer ACT, the gate electrode TGA is disposed on the gate insulating layer GI, the protective layer 127 is disposed on the gate electrode TGA, the semiconductor layer ACT, and the buffer layer 122. The planarization layer 128 is disposed on the protective layer 127. A fourth contact hole extends through the protective layer 127 and the planarization layer 128. The anode electrode layer 131 is disposed on the planarization layer 128. The third contact structure CNT3 includes the anode electrode layer 131 disposed on the planarization layer 128, and the third contact hole filled with, for example, the material of the semiconductor layer ACT and the fourth contact hole filled with, for example, the material of the anode electrode layer 131.

Via the fourth contact hole of the third pixel structure CNT, the anode electrode layer 131 connected to the pixel PXL contacts the semiconductor layer ACT. In addition, via the third contact hole of the third pixel structure CNT, one side of the semiconductor layer ACT contacts the light shielding layer 121. In this regard, a portion of the semiconductor layer ACT vertically overlapping the gate electrode TGA may act as a channel area of the driving transistor DT.

In one side around a position at which the third contact hole contacts the light shielding layer 121, that is, in an area in which the driving transistor DT is absent, the semiconductor layer ACT, the gate electrode TGA and the gate insulating layer GI are omitted, such that the protective layer 127 is disposed on the buffer layer 122.

The semiconductor layer ACT may include a silicon-based semiconductor material. For example, the semiconductor layer ACT may include polysilicon or low-temperature polysilicon. For example, the semiconductor layer ACT may include an oxide semiconductor material. Accordingly, the semiconductor layer ACT of the driving transistor DT may be embodied as one of an oxide semiconductor layer or a low-temperature polysilicon semiconductor layer or a combination thereof.

The semiconductor layer ACT of the driving transistor DT may include a channel area and source and drain areas respectively defined on both opposing sides of the channel area. An area of the semiconductor layer ACT vertically overlapping the gate electrode TGA may be the channel area. For example, an area of the semiconductor layer ACT vertically overlapping the gate electrode TGA may be the channel area. The source and drain areas SD may be disposed on both opposing sides of the channel area CH, respectively.

The gate insulating layer GI may be disposed between the semiconductor layer ACT and the gate electrode TGA. The gate insulating layer GI may be formed as a single layer or a stack of a plurality of layers made of silicon oxide (SiOx) or silicon nitride (SiNx). A low-reflective material may be applied as a material of the gate insulating layer GI.

The gate electrode TGA may be formed as a single layer or a stack of multiple layers made of one of molybdenum (Mo), aluminum (Al), chromium (Cr), gold (Au), titanium (Ti), nickel (Ni), neodymium (Nd), and copper (Cu) or an alloy thereof. A low reflective material may be applied as the material of the gate electrode TGA.

The protective layer 127 may include an inorganic insulating layer including silicon oxide (SiOx) or silicon nitride (SiNx). The protective layer 127 may act as a passivation layer.

As described above, the display device may include the third contact structure CNT3 including the fourth contact hole extending through the planarization layer 128 and the protective layer 127 and the third contact hole extending through the buffer layer 122. The anode electrode layer 131 connected to the pixel PXL is connected to the semiconductor layer ACT via the fourth contact hole which does not extend through the gate insulating layer GI. This is because in one side around a position at which the third contact hole contacts the light shielding layer 121, that is, in an area in which the driving transistor DT is absent, the semiconductor layer ACT, the gate electrode TGA and the gate insulating layer GI are omitted, such that the protective layer 127 is disposed on the buffer layer 122. The semiconductor layer ACT contacts the light shielding layer 121 via the third contact hole extending through the buffer layer 122.

In forming the third contact structure CNT3, the etching process of the gate insulating layer GI may be eliminated. Thus, the gate electrode TGA of the driving transistor DT may be made of a low reflective metal. Accordingly, the display device according to the exemplary embodiment of the present disclosure may reduce the reflectance of the display panel.

As described above, the display device includes the third contact structure CNT3 via which the semiconductor layer ACT is in contact with the anode electrode of the light-emitting element and the light shielding layer 121. The contact hole does not extend through the gate insulating layer GI but extends through at least one of the buffer layer 122, the protective layer 127, and the planarization layer 128. This allows the gate electrode of the driving transistor DT to be made of a low reflective metal, such that the reflectance of the display panel may be lowered.

The display device according to various aspects and embodiments of the present disclosure may be described as follows.

One embodiment of the present disclosure provides a display device comprising: a display panel including a plurality of pixels, each pixel including a light-emitting element and a driving transistor, wherein each of the pixels includes a light emission area including the light-emitting element and a circuit area including the driving transistor, wherein the circuit area includes: a first contact structure via which a first semiconductor layer is electrically connected to a light shielding layer disposed in the circuit area; a second contact structure via which a first electrode is electrically connected to a gate electrode of the driving transistor and to a second semiconductor layer spaced from the first semiconductor layer such that the gate electrode of the driving transistor is electrically connected to the second semiconductor layer; and a third contact structure via which an anode electrode layer extending from an anode electrode of the light-emitting element is electrically connected to a semiconductor layer of the driving transistor and to the light shielding layer.

In accordance with some embodiments, the light shielding layer acts as at least one of a power line, a data line, and a reference voltage line.

In accordance with some embodiments, in a portion of the circuit area corresponding to the first contact structure, the light shielding layer is disposed on a substrate; a buffer layer is disposed on the light shielding layer; and the first semiconductor layer is disposed on the buffer layer, wherein the first contact structure includes a contact hole extending through the buffer layer, wherein the first semiconductor layer is electrically connected to the light shielding layer via the contact hole.

In accordance with some embodiments, the light shielding layer acts as one of a power line, a data line, and a reference voltage line, wherein the first semiconductor layer electrically connected to the light shielding layer acts as a sub-line branching from one of the power line, the data line, and the reference voltage line.

In accordance with some embodiments, in a portion of the circuit area corresponding to the second contact structure, a buffer layer is disposed on a substrate; the second semiconductor layer is disposed on the buffer layer; a gate insulating layer is disposed on the semiconductor layer; the gate electrode of the driving transistor is disposed on the gate insulating layer; a protective layer is disposed on the gate electrode; a planarization layer is disposed on the protective layer; and the first electrode is disposed on the planarization layer, wherein the second contact structure includes a contact hole extending through the protective layer and the planarization layer, wherein the first electrode is electrically connected to the gate electrode of the driving transistor and to the second semiconductor layer via the contact hole.

In accordance with some embodiments, the second semiconductor layer electrically connected to the gate electrode acts as one electrode of a capacitor of the pixel.

In accordance with some embodiments, the first electrode contacting the second contact structure is made of the same material as a material of an anode electrode of the light-emitting element.

In accordance with some embodiments, in a portion of the circuit area corresponding to the third contact structure, the light shielding layer is disposed on a substrate; a buffer layer is disposed on the light shielding layer; the semiconductor layer of the driving transistor is disposed on the buffer layer; a gate insulating layer is disposed on the semiconductor layer; the gate electrode is disposed on the gate insulating layer; a protective layer is disposed on the gate electrode, the semiconductor layer, and the buffer layer; a planarization layer disposed on the protective layer; the anode electrode layer is disposed on the planarization layer, wherein the third contact structure includes: a first contact hole extending through the buffer layer, wherein the semiconductor layer of the driving transistor is electrically connected to the light shielding layer via the first contact hole; and a second contact hole extending through the protective layer and the planarization layer, wherein the anode electrode layer is electrically connected to the semiconductor layer of the driving transistor via the second contact hole.

In accordance with some embodiments, a portion of the semiconductor layer of the driving transistor vertically overlapping the gate electrode layer acts as a channel area of the driving transistor.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a display panel including a plurality of pixels, each of the plurality of pixels including a light-emitting element and a driving transistor,
wherein each of the plurality of pixels includes a light emission area including the light-emitting element and a circuit area including the driving transistor,
wherein the circuit area includes:
a first contact structure via which a first semiconductor layer is electrically connected to a light shielding layer disposed in the circuit area;
a second contact structure via which a first electrode is electrically connected to a gate electrode of the driving transistor and to a second semiconductor layer that is separate from the first semiconductor layer such that the gate electrode of the driving transistor is electrically connected to the second semiconductor layer; and
a third contact structure via which an anode electrode layer extending from an anode electrode of the light-emitting element is electrically connected to a semiconductor layer of the driving transistor and to the light shielding layer.

2. The display device of claim 1, wherein the light shielding layer is at least one of a power line, a data line, or a reference voltage line.

3. The display device of claim 1, wherein in a portion of the circuit area corresponding to the first contact structure,
the light shielding layer is on a substrate;
a buffer layer is on the light shielding layer; and
the first semiconductor layer is on the buffer layer,
wherein the first contact structure includes a contact hole extending through the buffer layer,
wherein the first semiconductor layer is electrically connected to the light shielding layer via the contact hole.

4. The display device of claim 3, wherein the light shielding layer is one of a power line, a data line, or a reference voltage line,
wherein the first semiconductor layer electrically connected to the light shielding layer is as a sub-line branching from one of the power line, the data line, and the reference voltage line.

5. The display device of claim 1, wherein in a portion of the circuit area corresponding to the second contact structure,
a buffer layer is on a substrate;
the second semiconductor layer is on the buffer layer;
a gate insulating layer is on the second semiconductor layer;
the gate electrode of the driving transistor is on the gate insulating layer;
a protective layer is on the gate electrode;
a planarization layer is on the protective layer; and
the first electrode is on the planarization layer,
wherein the second contact structure includes a contact hole extending through the protective layer and the planarization layer,
wherein the first electrode is electrically connected to the gate electrode of the driving transistor and to the second semiconductor layer via the contact hole.

6. The display device of claim 5, wherein the second semiconductor layer electrically connected to the gate electrode of the driving transistor is one electrode of a capacitor of the pixel.

7. The display device of claim 5, wherein the first electrode contacting the second contact structure includes a same material as a material of an anode electrode of the light-emitting element.

8. The display device of claim 1, wherein in a portion of the circuit area corresponding to the third contact structure,
the light shielding layer is on a substrate;
a buffer layer is on the light shielding layer;
the semiconductor layer of the driving transistor is on the buffer layer;
a gate insulating layer is on the semiconductor layer;
the gate electrode is on the gate insulating layer;
a protective layer is on the gate electrode, the semiconductor layer, and the buffer layer;
a planarization layer on the protective layer;
the anode electrode layer is on the planarization layer,
wherein the third contact structure includes:
a first contact hole extending through the buffer layer, wherein the semiconductor layer of the driving transistor is electrically connected to the light shielding layer via the first contact hole; and
a second contact hole extending through the protective layer and the planarization layer, wherein the anode electrode layer is electrically connected to the semiconductor layer of the driving transistor via the second contact hole.

9. The display device of claim 8, wherein a portion of the semiconductor layer of the driving transistor vertically overlapping the gate electrode is a channel area of the driving transistor.
